(19) United States
(12) Patent Application Publication
(10) Pub. No.: US 2025/0372941 A1
(43) Pub. Date: Dec. 4, 2025

(54) OPTICAL MODULE PACKAGING STRUCTURE AND METHOD OF MANUFACTURING THE SAME

(71) Applicant: PRIMAX ELECTRONICS LTD., Taipei City (TW)

(72) Inventor: SHENG-HSIANG CHIU, Taipei City (TW)

(21) Appl. No.: 18/749,648

(22) Filed: Jun. 21, 2024

(30) Foreign Application Priority Data
May 28, 2024 (TW) 113119648

(51) Int. Cl. H01S 5/0232; H01S 5/0236; H01S 5/026

(52) U.S. Cl. CPC H01S 5/0232; H01S 5/0236; H01S 5/0262

(57) ABSTRACT

An optical module packaging structure includes a first circuit board, an electronic component, first and second lead frames, a light emitting module and a second circuit board. The electronic component is disposed over the first circuit board. The first and second lead frames are disposed over the electronic component and electrically connected to the first circuit board. The light emitting module is disposed over the first and second lead frames and includes first and second connection pads electrically insulated from each other and located at bottom thereof. The second circuit board is disposed between the first and second lead frames and the bottom of the light emitting module and includes first and second conductive paths electrically insulated from each other. The first and second connection pads are electrically connected to the first and second lead frames through the first and second conductive paths, respectively.

### FIELD OF THE INVENTION

The present disclosure relates to an optical module packaging structure and a method of manufacturing the same.

### BACKGROUND OF THE INVENTION

As a size of an electronic product becomes thinner and smaller, a packaging structure inside the electronic product continues to develop toward miniaturization. Therefore, how to further reduce a volume of the packaging structure has become a technical issue in this field.

### SUMMARY OF THE INVENTION

The present invention provides an optical module packaging structure, which includes a first circuit board, an electronic component, a first lead frame and a second lead frame, a light emitting module and a second circuit board. The electronic component is disposed over the first circuit board. The first lead frame and the second lead frame are adjacent to each other and disposed over the electronic component, and electrically connected to the first circuit board. The light emitting module is disposed over the first lead frame and the second lead frame, in which the light emitting module includes a first connection pad and a second connection pad electrically insulated from each other and located at bottom of the light emitting module. The second circuit board is disposed between the first and second lead frames and the bottom of the light emitting module, and includes a first conductive path and a second conductive path electrically insulated from each other, in which the first connection pad and the second connection pad are electrically connected to the first lead frame and the second lead frame through the first conductive path and the second conductive path, respectively.

In some embodiments of the present disclosure, the light emitting module further includes a vertical-cavity surface-emitting laser (VCSEL).

In some embodiments of the present disclosure, the optical module packaging structure further includes a light receiving module laterally adjacent to the light emitting module, in which a height at which a top surface of the light emitting module is located is the same or substantially the same as a height at which a top surface of the light receiving module is located.

In some embodiments of the present disclosure, the first conductive path has a first top conductive pad and two first bottom conductive pads separated from each other, and the first top conductive pad is electrically connected to the first connection pad of the light emitting module, and the two first bottom conductive pads are electrically connected to the first lead frame.

In some embodiments of the present disclosure, the second circuit board has two recesses opposite to each other, and from a top view, the two recesses are located between one end of the first lead frame and one end of the second lead frame and between another end of the first lead frame and another end of the second lead frame, respectively.

In some embodiments of the present disclosure, a width of each of the recesses is smaller than a distance between the first lead frame and the second lead frame.

In some embodiments of the present disclosure, a vertical projection of each of the recesses overlaps a vertical projection of the electronic component.

In some embodiments of the present disclosure, the optical module packaging structure further includes a cured adhesive layer between the electronic component and the first and second lead frames and in the two recesses.

In some embodiments of the present disclosure, the cured adhesive layer is formed from a light-curing and heat-curing adhesive by curing.

In some embodiments of the present disclosure, the two recesses are two side holes.

In some embodiments of the present disclosure, the first lead frame and the second lead frame are fixed to a bottom surface of the second circuit board through a first solder paste, and the bottom of the light emitting module is fixed to a top surface of the second circuit board through a second solder paste.

The present invention further provides a method of manufacturing an optical module packaging structure, which includes: receiving a first circuit board and an electronic component located on the first circuit board; fixing a first lead frame and a second lead frame to a bottom surface of a second circuit board through a surface mount technology (SMT) process to form a first stacked structure; fixing a light emitting module to a top surface of the second circuit board of the first stacked structure through another surface mount technology process to form a second stacked structure; fixing the first lead frame and the second lead frame of the second stacked structure to the electronic component; and enabling the first lead frame and the second lead frame to be electrically connected to the first circuit board.

In some embodiments of the present disclosure, fixing the first lead frame and the second lead frame of the second stacked structure to the electronic component includes fixing the first lead frame and the second lead frame of the second stacked structure to the electronic component through a die bond process.

In some embodiments of the present disclosure, fixing the first lead frame and the second lead frame of the second stacked structure to the electronic component includes: dispensing a light-curing and heat-curing adhesive on the electronic component; placing the second stacked structure on the light-curing and heat-curing adhesive and the electronic component, so that the first lead frame and the second lead frame are in contact with the light-curing and heat-curing adhesive; illuminating the light-curing and heat-curing adhesive to partially cure the light-curing and heat-curing adhesive; and performing a heating process on the partially cured light-curing and heat-curing adhesive to form a cured adhesive layer.

In some embodiments of the present disclosure, the second circuit board has two recesses opposite to each other, and from a top view, the two recesses are between one end of the first lead frame and one end of the second lead frame and between another end of the first lead frame and another end of the second lead frame, respectively, and placing the second stacked structure on the light-curing and heat-curing adhesive and the electronic component further includes enabling the light-curing and heat-curing adhesive to enter the two recesses.

### BRIEF DESCRIPTION OF THE DRAWINGS

Aspects of the present disclosure are best understood from the following embodiments, read in conjunction with accompanying drawings. However, it should be understood that in accordance with common practice in the industry, various features have not necessarily been drawn to scale. Indeed, shapes of the various features may be suitably adjusted for clarity, and dimensions of the various features may be arbitrarily increased or decreased.

FIG. 1 is a perspective view of an optical module packaging structure according to an embodiment of the present invention.

FIG. 2 is a top perspective exploded view of a first lead frame, a second lead frame, a light emitting module and a second circuit board of FIG. 1.

FIG. 3 is a bottom perspective exploded view of the first lead frame, the second lead frame, the light emitting module and the second circuit board of FIG. 1.

FIGS. 4 to 10 are perspective views of various process stages of a method of manufacturing an optical module packaging structure according to an embodiment of the present invention.

### DETAILED DESCRIPTION OF THE PREFERRED EMBODIMENT

The advantages and features of the present disclosure and the method for achieving the same will be described in more detail with reference to exemplary embodiments and accompanying drawings to make it easier to understand. However, the present disclosure can be implemented in different forms and should not be construed as being limited to the embodiments set forth herein. On the contrary, for those skilled in the art, the provided embodiments will make this disclosure more thorough, comprehensive and complete to convey the scope of the present disclosure.

The spatially relative terms in the text, such as “beneath” and “over”, are used to facilitate the description of the relative relationship between one element or feature and another element or feature in the drawings. The true meaning of the spatially relative terms includes other orientations. For example, when the drawing is flipped up and down by 180°, the relationship between the one element and the other element may change from “beneath” to “over.” The spatially relative descriptions used herein should be interpreted the same.

As mentioned in background of the invention, how to further reduce the volume of the packaging structure has become the technical issue in this field. Accordingly, the present invention provides an optical module packaging structure, which includes a first circuit board, an electronic component, a first lead frame and a second lead frame, a light emitting module and a second circuit board. Compared with a packaging structure in which an electronic component and a light emitting module are disposed at different plane positions, the electronic component and the light emitting module of the present invention are stacked vertically, so those occupy a smaller plane space (i.e., X/Y dimensions). In another aspect, in the packaging structure of the present invention, an extremely small light emitting module, a very small second circuit board and thin and light lead frames are used as electrical connections between the light emitting module and the first circuit board, so that the packaging structure of the present invention is extremely small and thus can be applied to various electronic products with miniaturized sizes (e.g., AR glasses or VR glasses). Furthermore, a height at which the light emitting module is located is the same or substantially the same as a height at which the light receiving module is located, so that an optical system has excellent alignment, optical performance and stability. Various embodiments of the optical module packaging structure of the present invention will be described in detail below.

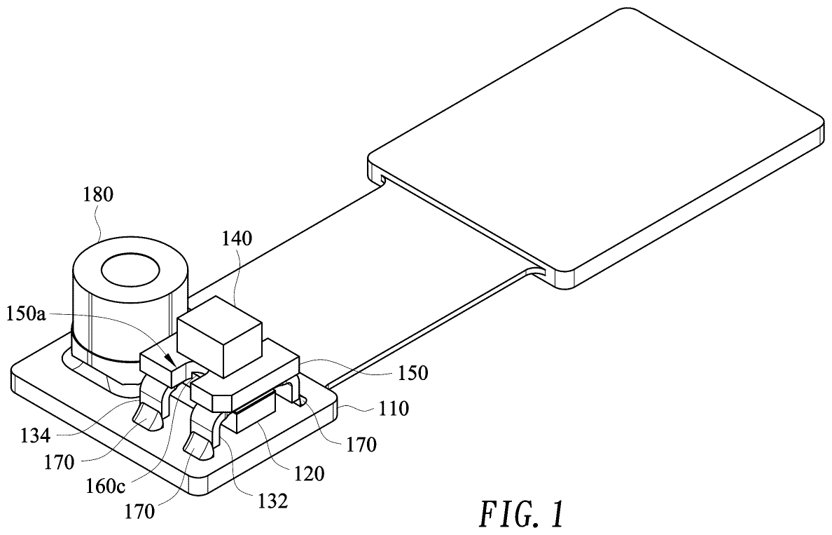

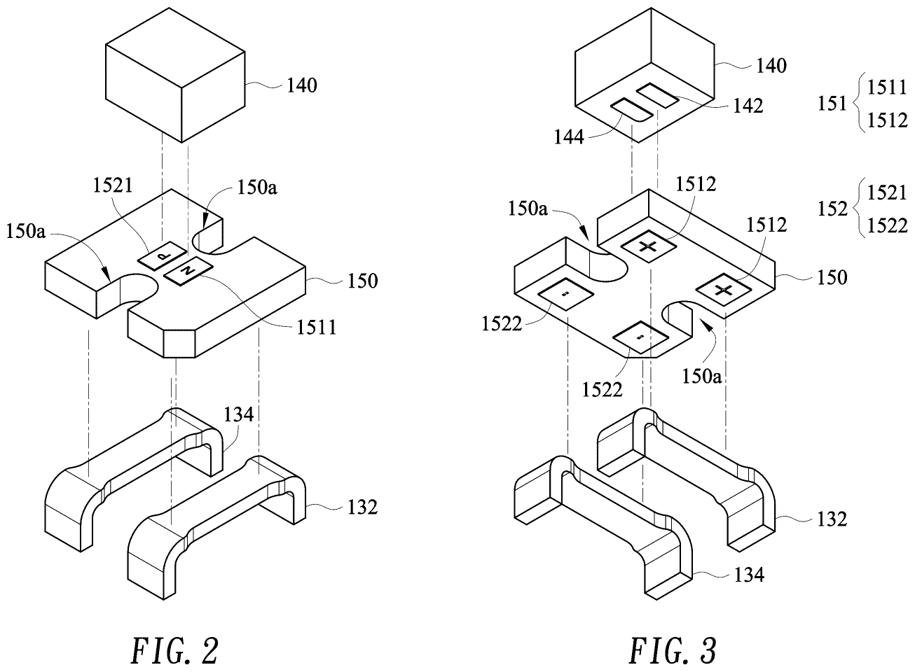

FIG. 1 is a perspective view of an optical module packaging structure according to an embodiment of the present invention. FIG. 2 is a top perspective exploded view of a first lead frame, a second lead frame, a light emitting module and a second circuit board of FIG. 1. FIG. 3 is a bottom perspective exploded view of the first lead frame, the second lead frame, the light emitting module and the second circuit board of FIG. 1. Referring to FIGS. 1 to 3, the optical module packaging structure includes a first circuit board 110, an electronic component 120, first and second lead frames 132 and 134, a light emitting module 140 and a second circuit board 150.

As shown in FIG. 1, the electronic component 120 is disposed over the first circuit board 110. In some embodiments, the electronic component 120 is electrically connected to the first circuit board 110. In some embodiments, the electronic component 120 is fixed to the first circuit board 110 through solder balls (not shown) or another suitable conductive component, and is electrically connected to the first circuit board 110 (e.g., an interconnection structure (not shown) in the first circuit board 110). In some embodiments, the electronic component 120 is a driver (e.g., a driver IC), a passive component, or another suitable electronic component.

As shown in FIG. 1, the first lead frame 132 and the second lead frame 134 are disposed over the electronic component 120 and are electrically connected to the first circuit board 110. The first lead frame 132 and the second lead frame 134 are adjacent to but separated from each other and not in contact with each other. In some embodiments, two ends of the first lead frame 132 and two ends of the second lead frame 134 are electrically connected to the first circuit board 110 through solders 170. However, the present invention is not limited to the foregoing embodiments. The first lead frame 132 and the second lead frame 134 may be electrically connected to the first circuit board 110 through other conductive components. In some embodiments, a thickness of the first lead frame 132/second lead frame 134 is less than or equal to 0.2 mm, or even less than or equal to 0.15 mm.

As shown in FIG. 1, the light emitting module 140 is disposed over the first lead frame 132 and the second lead frame 134. As shown in FIG. 3, the light emitting module 140 includes a first connection pad 142 and a second connection pad 144 electrically insulated from each other and located at bottom of the light emitting module 140. In some embodiments, the bottom of the light emitting module 140 has an insulating substrate (e.g., a plastic substrate or a ceramic substrate), and the first connection pad 142 and the second connection pad 144 are exposed from a bottom surface of the insulating substrate.

In some embodiments, the light emitting module 140 further includes a vertical-cavity surface-emitting laser (VCSEL) (not shown) or another suitable light emitting component. In some embodiments, the light emitting module 140 is a packaging structure of the vertical-cavity surface-emitter laser.

The second circuit board 150 is disposed between the first and second lead frames 132 and 134 and the bottom of the light emitting module 140, and includes a first conductive path 151 and a second conductive path 152 electrically insulated from each other.

In some embodiments, as shown in FIGS. 2 and 3, the first conductive path 151 has a first top conductive pad 1511 and two first bottom conductive pads 1512 separated from each other. The first top conductive pad 1511 is electrically connected to the two first bottom conductive pads 1512, and the first top conductive pad 1511 is electrically connected to the first connection pad 142 of the light emitting module 140, and the two first bottom conductive pads 1512 are electrically connected to the first lead frame 132.

In some embodiments, the second conductive path 152 has a second top conductive pad 1521 and two second bottom conductive pads 1522 separated from each other. The second top conductive pad 1521 is electrically connected to the two second bottom conductive pads 1522, and the second top conductive pad 1521 is electrically connected to the second connection pad 144 of the light emitting module 140, and the two second bottom conductive pads 1522 are electrically connected to the second lead frame 134.

In some embodiments, a solder mask (not shown) is provided on a bottom surface of the second circuit board 150, and the solder mask has four through holes to expose the two first bottom conductive pads 1512 and the two second bottom conductive pads 1522.

The first connection pad 142 and the second connection pad 144 are electrically connected to the first lead frame 132 and the second lead frame 134 through the first conductive path 151 and the second conductive path 152, respectively (as shown in FIGS. 2 and 3), and then are electrically connected to the first circuit board 110 through the first lead frame 132 and the second lead frame 134, respectively (as shown in FIG. 1).

In some embodiments, the vertical-cavity surface-emitting laser of the light emitting module 140 is electrically connected to the first connection pad 142 and the second connection pad 144. In some embodiments, referring to FIGS. 1 to 3, the electronic component 120 is a driver electrically connected to the first circuit board 110, and the driver is electrically connected to the first connection pad 142/second connection pad 144 sequentially through the first circuit board 110 (e.g., the interconnection structure in the first circuit board 110), the first lead frame 132/second lead frame 134 and the first conductive path 151/second conductive path 152 to stabilize a power output of the vertical-cavity surface-emitting laser to stabilize its emission wavelength so as to comply with standard IEC60825 or other safety standards for laser products.

In some embodiments, the first lead frame 132 and the second lead frame 134 are fixed to the bottom surface of the second circuit board 150 through a first solder paste (not shown), and the bottom of the light emitting module 140 is fixed to a top surface of the second circuit board 150 through a second solder paste (not shown). In some embodiments, the first solder paste is disposed between the two first bottom conductive pads 1512 and the first lead frame 132 and between the two second bottom conductive pads 1522 and the second lead frame 134. The first solder paste is in a form of dots rather than strips. In some embodiments, the second solder paste is disposed between the first top conductive pad 1511 and the first connection pad 142 and between the second top conductive pad 1521 and the second connection pad 144. The second solder paste is in a form of dots rather than strips.

It is worth noting that compared to silver glue (containing silver particles, binding agents, etc.), the solder paste has better thermal conductivity, so the second solder paste, the first conductive path 151/second conductive path 152 of the second circuit board 150, the first solder paste, and the first lead frame 132/second lead frame 134 can effectively conduct heat energy generated during operation of the light emitting module 140 to the outside, so the packaging structure of the present invention has excellent heat dissipation performance. In addition, the solder paste can provide high bonding strength between metals (e.g., between the first connection pad 142/second connection pad 144 and the first top conductive pad 1511/second top conductive pad 1521, and between the first bottom conductive pads 1512/second bottom conductive pads 1522 and the first lead frame 132/second lead frame 134). Therefore, there is high bonding strength between the light emitting module 140 and the second circuit board 150 and between the second circuit board 150 and the first and second lead frames 132 and 134.

In some embodiments, the second circuit board 150 has two recesses 150a opposite to each other. As shown in FIGS. 1 and 2, from a top view, the two recesses 150a are respectively between one end of the first lead frame 132 and one end of the second lead frame 134 and between another end of the first lead frame 132 and another end of the second lead frame 134. In some embodiments, a width of each of the recesses 150a is smaller than a distance between the first lead frame 132 and the second lead frame 134. In some embodiments, as shown in FIG. 1, a vertical projection of each of the recesses 150a overlaps a vertical projection of the electronic component 120. In some embodiments, as shown in FIG. 2, the two recesses 150a are two side holes. In some embodiments, the two recesses 150a are through holes (as shown in FIG. 2) or blind holes.

In some embodiments, as shown in FIG. 1, the optical module packaging structure further includes a cured adhesive layer 160c between the electronic component 120 and the first and second lead frames 132 and 134 and in the two recesses 150a. In some embodiments, the cured adhesive layer 160c is in contact with the second circuit board 150 but not in contact with the light emitting module 140. In some embodiments, the cured adhesive layer 160c is formed by curing a light-curing and heat-curing adhesive through a lighting process and a heating process.

In some embodiments, the optical module packaging structure further includes a light receiving module 180 laterally adjacent to the light emitting module 140. In some embodiments, the light receiving module 180 has a light sensor. In some embodiments, the light receiving module 180 is a camera module. In some embodiments, a height at which a top surface of the light emitting module 140 is located is the same or substantially the same as a height at which a top surface of the light receiving module 180. As such, the optical system can be ensured to have excellent alignment to obtain clear and accurate images. It can also reduce an optical path difference in a propagation path of light from an emitting end to a receiving end, so that the optical system has excellent optical performance and stability. In addition, a packaging structure in which a height of the light emitting module is inconsistent with a height of the light receiving module may require additional calibration and adjustment steps to ensure their alignment, resulting in additional cost and time. However, the above-mentioned embodiments of the present invention do not require additional cost and time.

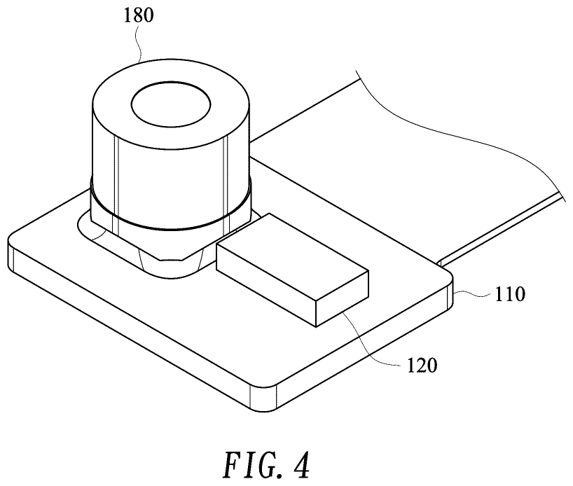

The present invention also provides a method of manufacturing an optical module packaging structure. FIGS. 4 to 10 are perspective views of various process stages of a method of manufacturing an optical module packaging structure according to an embodiment of the present invention. Each step of the manufacturing method of the present invention will be described in detail below.

As shown in FIG. 4, a first circuit board 110 and an electronic component 120 are received, and the electronic component 120 is located on the first circuit board 110. In some embodiments, a light receiving module 180 is also located on the first circuit board 110. In some embodiments, the electronic component 120 and/or the light receiving module 180 is fixed to the first circuit board 110 through solder balls or another suitable conductive component to electrically connect to the first circuit board 110. In some embodiments, the electronic component 120 and/or the light receiving module 180 is fixed to the first circuit board 110 through a surface mount technology (SMT) process. In some embodiments, the electronic component 120 is a driver, a passive component, or another suitable electronic component.

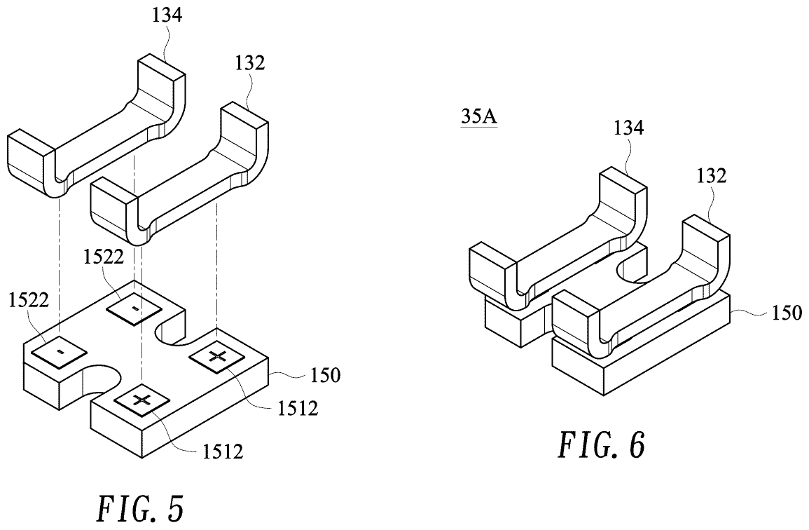

As shown in FIGS. 5 and 6, a first lead frame 132 and a second lead frame 134 are fixed to a bottom surface of the second circuit board 150 through a surface mount technology process to form a first stacked structure 35A. In some embodiments, a first solder paste (not shown) is printed on first bottom conductive pads 1512 and second bottom conductive pads 1522, and the first lead frame 132 and the second lead frame 134 are then mounted onto the first bottom conductive pads 1512 and the second bottom conductive pads 1522, respectively.

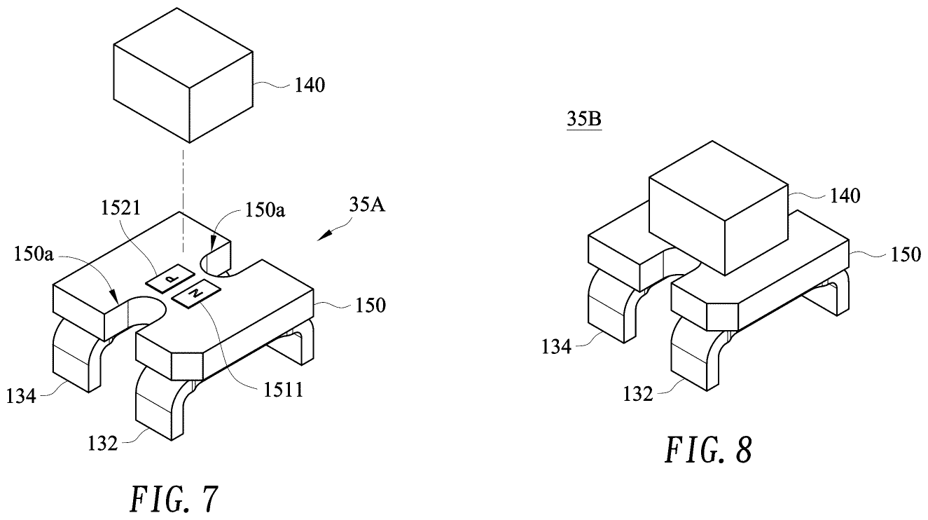

As shown in FIGS. 7 and 8, a light emitting module 140 is fixed to a top surface of the second circuit board 150 of the first stacked structure 35A through another surface mount technology process to form a second stacked structure 35B. In some embodiments, a second solder paste (not shown) is printed on a first top conductive pad 1511 and a second top conductive pad 1521, and the light emitting module 140 is then mounted onto the first top conductive pad 1511 and the second top conductive pad 1521.

As shown in FIGS. 8 to 10, the first lead frame 132 and the second lead frame 134 of the second stacked structure 35B are fixed to the electronic component 120. In some embodiments, the step of fixing the first lead frame 132 and the second lead frame 134 of the second stacked structure 35B to the electronic component 120 includes: fixing the first lead frame 132 and the second lead frame 134 of the second stacked structure 35B to the electronic component 120 through a die bond process.

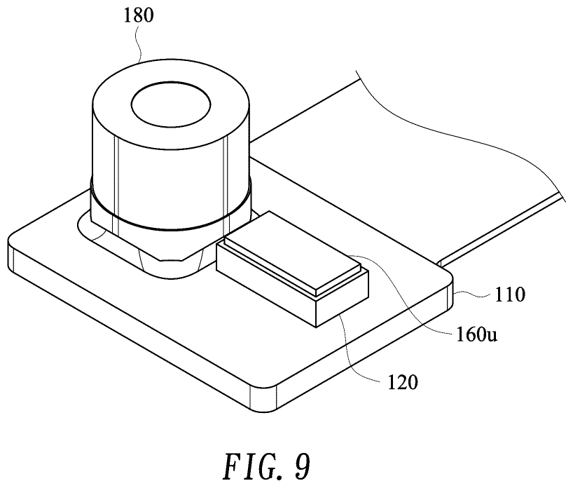

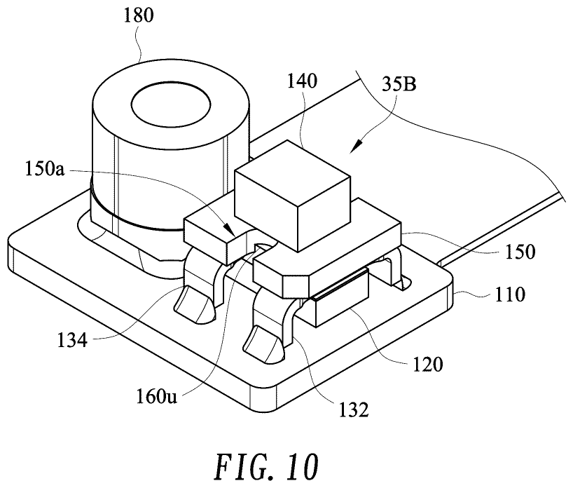

In some embodiments, the step of fixing the first lead frame 132 and the second lead frame 134 of the second stacked structure 35B to the electronic component 120 includes: dispensing a light-curing and heat-curing adhesive 160u on the electronic component 120 (as shown in FIG. 9); placing the second stacked structure 35B as shown in FIG. 8 on the light-curing and heat-curing adhesive 160u and the electronic component 120, so that the first lead frame 132 and the second lead frame 134 are in contact with the light-curing and heat-curing adhesive 160u (as shown in FIG. 10); illuminating the light-curing and heat-curing adhesive 160u to partially cure (or can be called pre-cure) the light-curing and heat-curing adhesive 160u; and performing a heating process on the partially cured light-curing and heat-curing adhesive to form a cured adhesive layer (not shown in FIG. 10, please refer to FIG. 1).

In some embodiments, as shown in FIG. 9, dispensing the light-curing and heat-curing adhesive 160u on the electronic component is conducted by a dispensing process. In some embodiments, the light-curing and heat-curing adhesive 160u includes a light-curing resin and a heat-curing resin. In some embodiments, the light-curing and heat-curing adhesive 160u further includes thermally conductive particles.

In some embodiments, as shown in FIGS. 8 to 10, the step of placing the second stacked structure 35B on the light-curing and heat-curing adhesive 160u and the electronic component 120 further includes: enabling the light-curing and heat-curing adhesive 160u to enter the two recesses 150a.

In some embodiments, referring to FIG. 10, the step of illuminating the light-curing and heat-curing adhesive 160u to partially cure the light-curing and heat-curing adhesive 160u includes: partially curing the light-curing and heat-curing adhesive 160u in and beneath the recesses 150a, thereby generating a certain bonding strength between the first and second lead frames 132 and 134 and the electronic component 120. In some embodiments, referring to FIG. 10, the step of illuminating the light-curing and heat-curing adhesive 160u includes: illuminating two opposite side surfaces of the light-curing and heat-curing adhesive 160u adjacent to the two recesses 150a.

In some embodiments, referring to FIG. 10, after a bond head (not shown) places the second stacked structure 35B on the light-curing and heat-curing adhesive 160u and the electronic component 120, the bond head does not move. After the light-curing and heat-curing adhesive 160u is illuminated to partially cure the light-curing and heat-curing adhesive 160u, the bond head moves up and away. As such, it is possible to avoid dragging the second stacking structure 35B when the bond head moves up and away and thus causing its position significantly shift (e.g., offset in X direction, Y direction and a rotation angle).

In some embodiments, since the light-curing and heat-curing adhesive 160u has been partially cured to produce the certain bonding strength, significant position shift of the second stacked structure 35B can also be avoided during a subsequent process of moving the packaging structure into an oven for the heating process.

As shown in FIGS. 10 and 1, the first lead frame 132 and the second lead frame 134 are electrically connected to the first circuit board 110. In some embodiments, the first lead frame 132 and the second lead frame 134 are electrically connected to the first circuit board 110 using a solder jet process to form solders 170 electrically connected between the first and second lead frames 132 and 134 and the first circuit board 110.

However, the above are only the preferred embodiments of the present disclosure, and should not be used to limit the scope of implementation of the present disclosure, that is, simple equivalent changes and modifications made in accordance with claims and description of the present disclosure are still within the scope of the present disclosure. In addition, any embodiment of the present disclosure or claim does not need to achieve all the objectives or advantages disclosed in the present disclosure. In addition, the abstract and the title are not intended to limit the scope of claims of the present disclosure.

What is claimed is:

1. An optical module packaging structure, comprising:
a first circuit board;
an electronic component, disposed over the first circuit board;
a first lead frame and a second lead frame, adjacent to each other and disposed over the electronic component, and electrically connected to the first circuit board;
a light emitting module, disposed over the first lead frame and the second lead frame, wherein the light emitting module comprises a first connection pad and a second connection pad electrically insulated from each other and located at bottom of the light emitting module; and
a second circuit board, disposed between the first and second lead frames and the bottom of the light emitting module, and comprises a first conductive path and a second conductive path electrically insulated from each other, wherein the first connection pad and the second connection pad are electrically connected to the first lead frame and the second lead frame through the first conductive path and the second conductive path, respectively.

2. The optical module packaging structure of claim 1, wherein the light emitting module further comprises a vertical-cavity surface-emitting laser (VCSEL).

3. The optical module packaging structure of claim 1, further comprising:
a light receiving module, laterally adjacent to the light emitting module, wherein a height at which a top surface of the light emitting module is located is the same or substantially the same as a height at which a top surface of the light receiving module is located.

4. The optical module packaging structure of claim 1, wherein the first conductive path has a first top conductive pad and two first bottom conductive pads separated from each other, and the first top conductive pad is electrically connected to the first connection pad of the light emitting module, and the two first bottom conductive pads are electrically connected to the first lead frame.

5. The optical module packaging structure of claim 1, wherein the second circuit board has two recesses opposite to each other, and from a top view, the two recesses are located between one end of the first lead frame and one end of the second lead frame and between another end of the first lead frame and another end of the second lead frame, respectively.

6. The optical module packaging structure of claim 5, wherein a width of each of the recesses is smaller than a distance between the first lead frame and the second lead frame.

7. The optical module packaging structure of claim 5, wherein a vertical projection of each of the recesses overlaps a vertical projection of the electronic component.

8. The optical module packaging structure of claim 5, further comprising:
a cured adhesive layer, between the electronic component and the first and second lead frames and in the two recesses.

9. The optical module packaging structure of claim 8, wherein the cured adhesive layer is formed from a light-curing and heat-curing adhesive by curing.

10. The optical module packaging structure of claim 5, wherein the two recesses are two side holes.

11. The optical module packaging structure of claim 1, wherein the first lead frame and the second lead frame are fixed to a bottom surface of the second circuit board through a first solder paste, and the bottom of the light emitting module is fixed to a top surface of the second circuit board through a second solder paste.

12. A method of manufacturing an optical module packaging structure, comprising:
receiving a first circuit board and an electronic component located on the first circuit board;
fixing a first lead frame and a second lead frame to a bottom surface of a second circuit board through a surface mount technology (SMT) process to form a first stacked structure;
fixing a light emitting module to a top surface of the second circuit board of the first stacked structure through another surface mount technology process to form a second stacked structure;
fixing the first lead frame and the second lead frame of the second stacked structure to the electronic component; and
enabling the first lead frame and the second lead frame to be electrically connected to the first circuit board.

13. The method of claim 11, wherein fixing the first lead frame and the second lead frame of the second stacked structure to the electronic component comprises fixing the first lead frame and the second lead frame of the second stacked structure to the electronic component through a die bond process.

14. The method of claim 11, wherein fixing the first lead frame and the second lead frame of the second stacked structure to the electronic component comprises:
dispensing a light-curing and heat-curing adhesive on the electronic component;
placing the second stacked structure on the light-curing and heat-curing adhesive and the electronic component, so that the first lead frame and the second lead frame are in contact with the light-curing and heat-curing adhesive;
illuminating the light-curing and heat-curing adhesive to partially cure the light-curing and heat-curing adhesive; and
performing a heating process on the partially cured light-curing and heat-curing adhesive to form a cured adhesive layer.

15. The method of claim 11, wherein the second circuit board has two recesses opposite to each other, and from a top view, the two recesses are between one end of the first lead frame and one end of the second lead frame and between another end of the first lead frame and another end of the second lead frame, respectively, and placing the second stacked structure on the light-curing and heat-curing adhesive and the electronic component further comprises enabling the light-curing and heat-curing adhesive to enter the two recesses.
